(19) United States
(12) Patent Application Publication
(10) Pub. No.: US 2015/0237750 A1
(43) Pub. Date: Aug. 20, 2015

(54) DETACHABLE MOUNTING SYSTEMS FOR ELECTRONIC DEVICES

(71) Applicant: The Joy Factory, Inc., Irvine, CA (US)

(72) Inventor: Sampson YANG, Irvine, CA (US)

(21) Appl. No.: 14/700,023

(22) Filed: Apr. 29, 2015

Related U.S. Application Data
(63) Continuation-in-part of application No. 13/624,833, filed on Sep. 21, 2012.
(60) Provisional application No. 61/537,489, filed on Sep. 21, 2011.

(51) Int. Cl. H05K 5/02; F16M 11/16; G08B 13/06; F16M 13/02; B60R 11/02; H05K 5/03; F16B 1/00

(52) U.S. Cl. CPC H05K 5/0234; H05K 5/03; F16M 11/16; F16B 1/00; F16M 13/022; B60R 11/02; H05K 5/023; G08B 13/06; F16B 2001/0035; B60R 2011/0007

(57) ABSTRACT

A detachable mounting system for securing an electronic device includes a protective housing for mounting to the electronic device. The protective housing includes a mounting piece. The system also includes a base capable of being coupled with a supporting surface and includes a securing device detachably coupled between the protective housing and the first end of the base for securing the protective housing. The system further includes a security alarm capable of detecting at least one of an attachment or detachment of the mounting piece to or from the securing device and a communication device configured to communicate to the security alarm a signal reflecting at least one of the attachment and the detachment.

### CROSS REFERENCE TO RELATED APPLICATION

This application is a continuation-in-part (CIP) application of U.S. patent application Ser. No. 13/624,833, filed on Sep. 21, 2012, which claims the benefit of priority to U.S. provisional Application No. 61/537,489 filed with the United States Patent and Trademark Office on Sep. 21, 2011, and entitled “DETACHABLE MOUNTING SYSTEMS FOR USER-OPERATIVE DEVICES.” All the above identified Applications are hereby incorporated by reference in their entirety.

### TECHNICAL FIELD

The subject matter of the present application relates to detachable mounting systems for electronic devices such as touch screen devices, various generations of iPad®, tablets, tablet PCs, smart phones, and other devices that a user may mount for easier operations.

### BACKGROUND

Portable electronic devices, such as Apple's Iphone®, various generations of Apple's iPad® (including iPad 2®, etc.), Samsung's Galaxy® or Galaxy series tablets, tablets, Android® tablets, tablet PCs, smart phones, other touch-panel devices, digital cameras, camcorders, e-readers, various generations of Kindle®, various generations of Nook®, and many other devices, are becoming more and more popular and have wide varieties of applications. Some of the applications may require a device to be easily mounted to an external object, but at the same time in a secure or substantially secure manner. Some of the applications may also require that the mounted devices still have certain degree or flexibility of movement. Thus, it may be desirable to have a flexible and/or secure detachable mounting system for electronic devices.

### SUMMARY

The present disclosure provides a detachable mounting system for securing an electronic device. According to one embodiment, the system includes a protective housing for mounting to the electronic device. The protective housing includes a mounting piece. The system also includes a base capable of being coupled with a supporting surface. The base includes a first end coupled to the protective housing, and a second end capable of being coupled with the supporting surface. At least one of couplings with the first and second ends enables at least one of relative horizontal, vertical, pivoting, swiveling, and rotating movements of the electronic device relative to the supporting surface. The system further includes a securing device detachably coupled between the protective housing and the first end of the base for securing the protective housing to the first end of the base through at least magnetic force between the mounting piece and the securing device. The system further includes a security alarm coupled to the security device. The security alarm is capable of detecting at least one of an attachment or detachment of the mounting piece to or from the securing device. The system further includes a communication device electrically coupled to the security alarm. The communication device is configured to communicate to the security alarm a signal representing at least one of the attachment and the detachment.

The present disclosure further provides a detachable mounting system for securing an electronic device. According to one embodiment, the system includes a protective housing for mounting to the electronic device. The protective housing includes a mounting piece. The system also includes a base capable of being coupled with a supporting surface. The base includes a first end coupled to the protective housing, and a second end capable of being coupled with the supporting surface. At least one of couplings with the first and second end enables at least one of relative horizontal, vertical, pivoting, swiveling, and rotating movements of the electronic device relative to the supporting surface. The system further includes a securing device detachably coupled between the protective housing and the first end of the base for securing the protective housing to the first end of the base through at least magnetic force between the mounting piece and the securing device. The system further includes a docking device integrated with the base. The docking device is configured to facilitate communication or convert signals between the electronic device and one or more external devices.

The present disclosure further provides a detachable mounting system for securing an electronic tablet. According to one embodiment, the system includes a protective housing for mounting to the electronic tablet. The protective housing includes a mounting piece and a rotatable platform that is rotatable with respect to a surface of the protective housing. The rotatable platform includes a hand-strap and a pullout stand. The system further includes a base capable of being coupled with a supporting surface. The base includes a first end being coupled to the protective housing, and a second end capable of being coupled with the supporting surface. At least one of couplings with the first and second end enables at least one of relative horizontal, vertical, pivoting, swiveling, and rotating movements of the electronic tablet relative to the supporting surface. The system further includes a securing device detachably coupled between the protective housing and the first end of the base for securing the protective housing to the first end of the second mounting body through at least magnetic force between the mounting piece and the securing device.

### DESCRIPTION OF THE DRAWINGS

FIG. 1 illustrates an exemplary detachable mounting system according to an embodiment of the present disclosure.

FIG. 2A illustrates a perspective view of a first end of a second mounting body of the detachable mounting system as shown in FIG. 1.

FIG. 2B illustrates a back view of the second mounting body as illustrated in FIG. 2A.

FIG. 2C illustrates a side view of the second mounting body as illustrated in FIG. 2A.

FIG. 2D illustrates a front view of the second mounting body as illustrated in FIG. 2A.

FIG. 3 illustrates a perspective view of the first mounting body or a mounting piece of the detachable mounting system as illustrated in FIG. 1.

FIG. 4 illustrates a perspective view of the first mounting body being attached to the second mounting body of the detachable mounting system as shown in FIG. 1.

FIG. 5 illustrates an exemplary embodiment of the detachable mounting system as shown in FIG. 1.

FIG. 6A illustrates an exemplary embodiment of the protective housing that includes a rotatable platform.

FIG. 6B illustrates a perspective view of an exemplary embodiment of the protective housing that includes a rotatable platform having a flexible hand-strap.

FIG. 6C illustrates another perspective view of an exemplary embodiment of the protective housing that includes a rotatable platform having a pullout stand.

FIG. 6D illustrates another perspective view of an exemplary embodiment of the protective housing that includes a pullout stand.

FIG. 7 illustrates a block diagram of another exemplary embodiment of a detachable mounting system.

FIG. 8A illustrates a block diagram of another exemplary embodiment of a detachable mounting system.

FIG. 8B illustrates a perspective view of an exemplary embodiment of a docking device that includes a communication interface.

### DETAILED DESCRIPTION

The aforementioned and other aspects, solutions, and advantages of the presently claimed subject matter will become apparent from the following descriptions and corresponding drawings. The embodiments further clarify the presently claimed subject matter and shall not be construed to limit the scope of the present claimed subject matter.

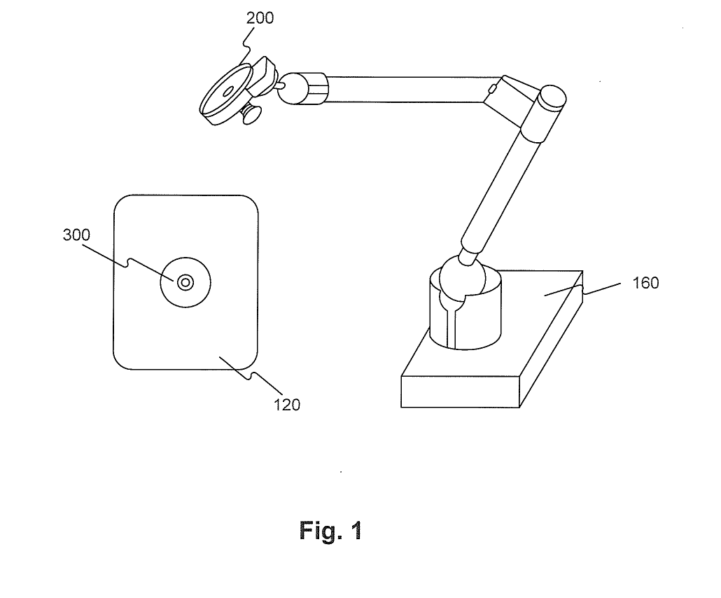

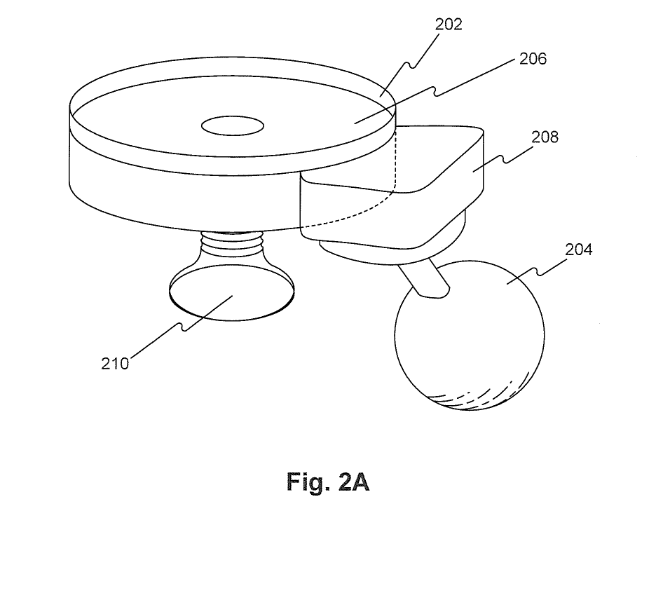

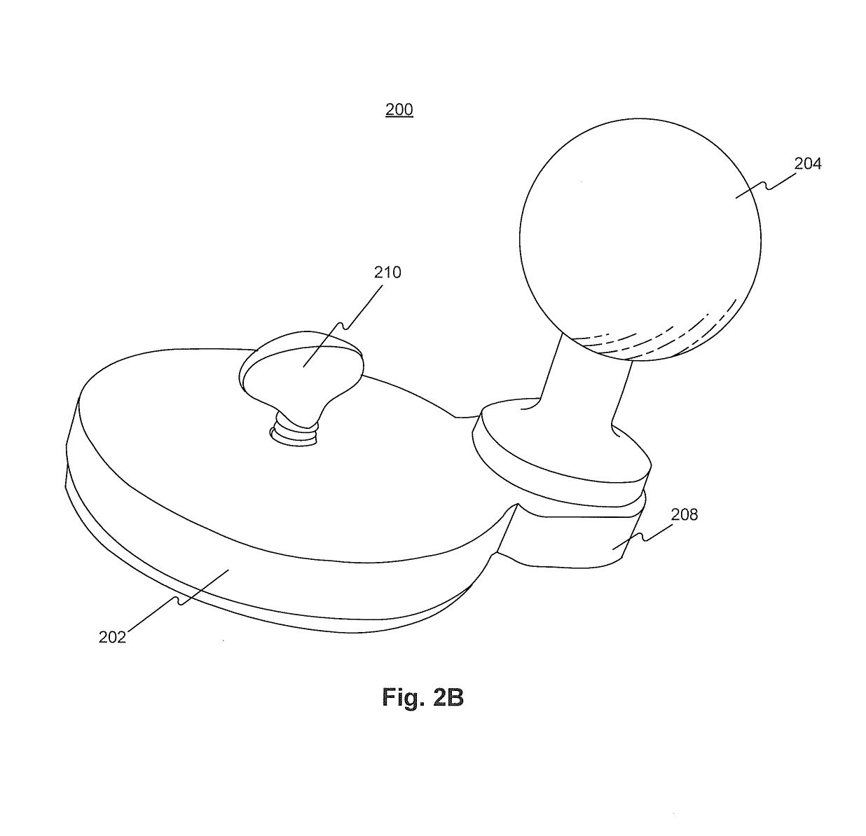

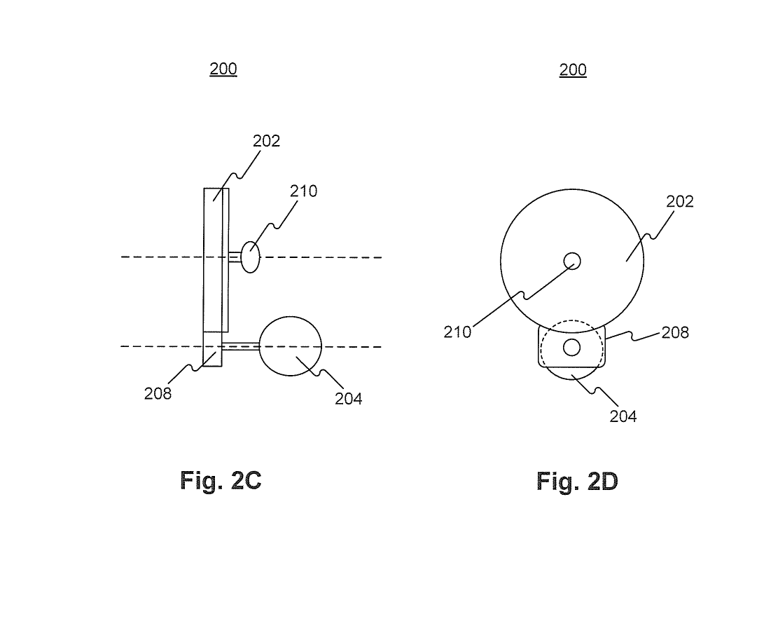

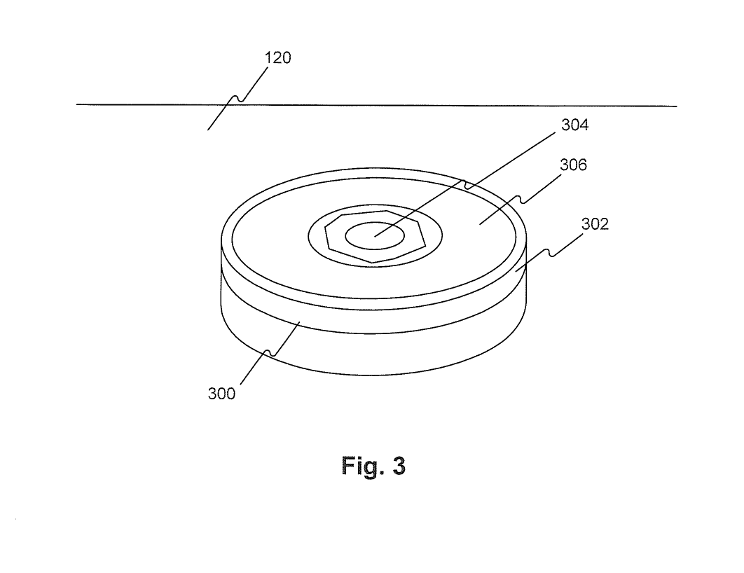

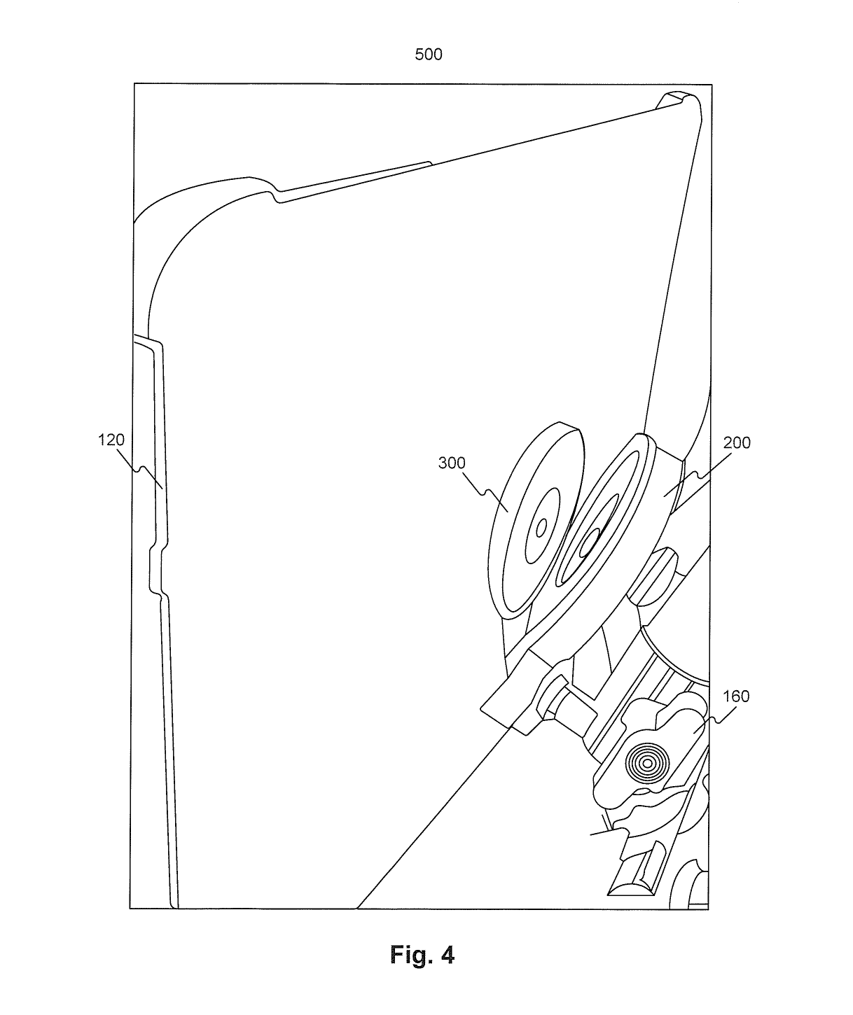

FIG. 1 illustrates an exemplary detachable mounting system 100 according to an embodiment of the present disclosure. As illustrated in FIG. 1, an exemplary detachable mounting system 100 can be used for securing an electronic device 120 and includes a first mounting body 300 that is coupled with the electronic device 120. In some embodiments, the electronic device 120 may include a protective housing that is coupled to or integrated with the first mounting body 300. The first mounting body 300 may include a magnetic mounting piece 306, an example of which is shown in FIG. 3. The detachable mounting system 100 also includes a second mounting body 200 that is capable of being coupled with a supporting base or surface 160. The second mounting body 200 is also referred to as a base 200. The second mounting body 200 may include a first end for being coupled to the first mounting body 300, and a second end for being coupled with the supporting base or surface 160. The detachable mounting system 100 also includes a magnetic securing device 206, an example of which is shown in FIG. 2A, which may be detachably coupled between the first mounting body 300 and a first end of the second mounting body 200 for securing the first mounting body 300 to the second mounting body 200 through at least magnetic force.

Referring to FIG. 1, the electronic device 120 may include one of a tablet PC, a tablet (such as an Android® tablet, an Apple iPad® of any generation, and an Ipad® mini of any generation), and a smart phone. The electronic device 120 may come with a protective housing, or the first mounting body 300 itself may provide a protective housing or have a case or base integrated or coupled with the magnetic mounting piece 306 (shown in FIG. 3). As an example, when the electronic device 120 is secured to the supporting base or surface 160 using the first mounting body 300 and the second mounting body 200, the electronic device 120 can be secured or mounted to prevent it from falling, shifting, dropping, lifting, dislocating, or engaging in other undesired movements, either when the electronic device 120 is not in use or is being operated by a user. Referring to FIG. 1, the supporting base or surface 160, which the exemplary detachable mounting system 100 may be coupled with, can provide support or stability to the system.

Referring still to FIG. 1, the first mounting body 300 can be coupled to one of the components of the detachable mounting system 100. As an example, the first mounting body 300 can be coupled to the second mounting body 200. The coupling between them can be through a magnetic securing device 206 (an example is shown in FIG. 2A) and/or the magnetic mounting piece 306 (example shown in FIG. 3). The first mounting body 300 is described in further detail below with reference to FIG. 3.

The second mounting body 200, as illustrated in FIG. 1, may include a first end that can be coupled to the first mounting body 300, and a second end that is capable of being coupled to the supporting base or surface 160. The second mounting body 200 may also include at least one movable or extendable arm (with two illustrated in FIG. 1) for providing maneuverability and freedom of movement of the electronic device 120. In some exemplary embodiments, the movable arm or arms coupled to the supporting base or surface 160 may enable at least one of relative horizontal, vertical, pivoting, swiveling, and rotating movements of the electronic device 120 relative to the supporting base or surface 160.

Accordingly, the second mounting body 200 can be coupled with or attached to both the first mounting body 300 and the supporting base or surface 160. With the detachable mounting system 100, the electronic device 120 can be secured, but can also be allowed to having movement, such as one or more horizontal, vertical, pivoting, swiveling, and rotating movements, relative to the supporting base or surface 160 or the second mounting body 200. Also, the various joints, clamps, screws illustrated here can be loosened or tightened to allow or restrain the degree of movements and provide the necessary flexibility or stability. As an example, when the first mounting body 300 is coupled to the first end of the second mounting body 200 and the supporting base or surface 160 is coupled to the second end of the second mounting body 200, the electronic device 120 can be secured or substantially secured relative to the supporting base or surface 160. The electronic device 120 can also move with one, two, three, or four degrees freedom relative to the supporting base or surface 160. The securing of the electronic device 120 by the detachable mounting system 100 and its controls, therefore, may allow ease of user operations including the re-positioning, tilting, swiveling, or rotating and horizontal and/or vertical movement of the electronic device 120.

In some exemplary embodiments, the second end of the second mounting body 200 may be coupled with the supporting base or surface 160 through a ball (or T-ball) or a substantially spherical joint to provide additional freedom of movement or adjustability. In one embodiment, the second or lower end of the second mounting body 200 may include one of a clamp, a screw mount, a wall/desk/ceiling mounting piece, and a dashboard, seatback, headrest, vent, window, sunroof, or center console mount for vehicles so the second mounting body can be mounted to various bases or surfaces. It is appreciated that the second end can have various shapes, mechanisms, or structures for enabling the securing of the second mounting body 200 to the supporting base or surface 160.

In some exemplary embodiments, the detachable mounting system 100 includes a magnetic securing device 206 (an example is shown in FIG. 2A), for the purpose of coupling to or securing the first mounting body 300, such as through the magnetic mounting piece 306. A quick-mount (or quick-release) securing device may be used with the magnetic mounting piece 306 for easy but secure (or securable) retention of the electronic device 120.

FIG. 2A illustrates a perspective view of the first end the second mounting body 200 of the detachable mounting system 100 as illustrated in FIG. 1. Referring to FIG. 2A, the second mounting body 200 includes a first portion 202 and a second portion 204. The first portion of the second mounting body 200 may include the magnetic securing device 206, which may be detachably coupled between the first mounting body 300 (shown in FIG. 1) and the first end of the second mounting body 200. The magnetic securing device 206 may further include a securing latch 210 or a securing and releasing latch 210.

Referring to FIG. 2A, the first portion 202 can be coupled to the first mounting body 300 (shown in FIG. 1). The first portion 202 may be a mounting cap or plate. As an example illustrated in FIG. 2A, the mounting cap or plate may be a round-shaped one and may have a protruded edge surrounding the cap or plate to increase the security of the coupling. The round shape of the first portion 202 (with or without the protruded edge) may enable the electronic device 120, which may be attached to the first mounting body 300 that fits within the first portion 202, to rotate freely while being attached or mounted. One of ordinary skill in the art would appreciate that the first portion 202 can have any other desired shape for enabling the coupling of the second mounting body 200 to the first mounting body 300.

Referring still to FIG. 2A, the second portion 204 can be a ball-joint or a pivoting or swiveling mechanism for enabling the coupling to the rest of the second mounting body 200, such as the portion coupled with the supporting base or surface 160. In FIG. 2A, as an example, the second portion 204 may include a ball, a T-ball, or a substantially spherical joint. Therefore, the various designs described above regarding the second mounting body 200 can enable at least one of relative horizontal, vertical, pivoting, swiveling, and rotating movements of the electronic device 120 relative to the second mounting body 200 or the supporting base or surface 160. Therefore, the second mounting body 200 may enable a user to adjust the positioning of the device 120 with various viewing, rotating, angular, horizontal, and vertical positions relative to the supporting base and surface 160.

Referring still to FIG. 2A, the second mounting body 200 includes a magnetic securing device 206, which may be detachably coupled between the first mounting body 300 (shown in FIG. 1) and the upper or first end of the second mounting body 200. The magnetic securing device 206 may include at least one of a permanent magnet and a ferromagnetic material. Similarly, the corresponding magnetic mounting piece 306 may include at least one of a permanent magnet and a ferromagnetic material so magnetic force would attract the magnetic securing device 206 to the corresponding magnetic mounting piece 306 or vice versa. In some exemplary embodiments, the permanent magnet may be a neodymium (NdFeB, NIB, or Neo) magnet. Thus, the magnetic securing device 206 can enable the securing of the first mounting body 300 through magnetic force that exists between the magnetic securing device 206 and an optional magnetic mounting piece 306 (shown in FIG. 3). As a result, when the first mounting body 300 is secured by the magnetic securing device 206, it can be prevented from falling, shifting, dropping, lifting, dislocating, or engaging in other undesired movements, which may be caused by gravity, vibration, force of a user operation, or a combination thereof.

As a non-limiting example, FIG. 2A illustrates that the magnetic securing device 206 is of a circular shape or a concentric shape. It is appreciated that any other desired shape may be implemented or used for obtaining a desired level of magnetic coupling. In some exemplary embodiments, a corresponding magnetic mounting piece 306 may be included in the first mounting body 300, as will be discussed below in association with FIG. 3.

Moreover, in some exemplary embodiments, the first portion 202 of the second mounting body 200 may further include an optional convex or attachment portion 208, for coupling the first portion 202 to the second portion 204. In FIG. 2A, as a non-limiting example, the convex or attachment portion 208 is located at the side of the first portion 202. The convex or attachment portion 208 can also be located directly under the first portion 202 while still allowing the securing and releasing latch 210 to pass through, so that the first portion 202 (such as a magnet and a screw) and second portion 204 (such as a joint or a ball or T-ball joint) are aligned along the same axis. It is appreciated that any other desired alignment or arrangement of the first portion 202 and the second portion 204 can be implemented, with or without the optional portion 208. In addition, the convex or attachment portion 208 can also enable a user to easily detach or separate the first mounting body 300 from the second mounting body 200, for example, with one hand when the magnetic coupling creates a tightened attachment.

Referring still to FIG. 2A, in some exemplary embodiments, the magnetic securing device 206 may further include the securing latch (or the securing and releasing latch) 210. The securing and releasing latch 210 may include one of a screw, a clamp, a lock, and a quick-release latch. The securing and releasing latch 210 can be coupled to the first portion 202 to screw into or clamp onto the magnetic mounting piece 306 (shown in FIG. 3). In some exemplary embodiments, an enhanced securing of the first mounting body 300 (and the electronic device 120 attached to it) may be desirable to provide additional security or rigidity. The securing and releasing latch 210 can provide additional security or protection by adding an additional securing or latching mechanism. As an example, in FIG. 2A, the first portion 202 may have an opening in its center so that the securing and releasing latch 210, such as a screw, can go through the opening to further secure the first mounting body 300. In this case, a corresponding screw thread may be provided in the first mounting body 300 or the magnetic mounting piece 306. In addition, when the first mounting body 300 is about to be decoupled from the second mounting body 200, the securing and releasing latch 210 can be un-screwed (or un-clamped/unlocked/unlatched) to release the coupling. Furthermore, the securing and releasing latch 210 may also be used as a quick-release latch for separation of the magnetic coupling provided by the magnetic securing device 206. For example, if the securing and releasing latch 210 is attached to the second mounting body 200 but not the first mounting body 300, a user can pull the securing and releasing latch 210 for separating the magnetically coupled bodies.

FIG. 2B illustrates a back view of the second mounting body 200 as illustrated in FIG. 2A. In FIG. 2B, as a non-limiting example, the securing and releasing latch 210 is shown as a screw that can be operated by hand. In addition, the magnetic securing device 206 may be enclosed in the first portion 202 and thus not shown in FIG. 2B. It is appreciated that the magnetic securing device 206 can be attached or coupled to the first portion 202 in any other manner not shown in FIG. 2B. Furthermore, the securing and releasing latch 210 may further include a security mechanism (not shown in FIG. 2B) comprising at least one of a lock, a security alarm, an electrically-controlled lock or magnet, a motion or decoupling sensor, an anti-theft screw for preventing unauthorized removal of the electronic device.

FIG. 2C illustrates a side view of the second mounting body 200 of the detachable mounting system 100 as illustrated in FIG. 2A. As also illustrated in FIG. 2C, the center axis (shown as line “A” extending horizontally in FIG. 2C) of the first portion 202, such as a mounting cap or plate, may or may not be aligned or parallel with the center/vertical axis of the second portion 204 (shown as line “B” extending horizontally in FIG. 2C). That is, the two axes can be parallel (as illustrated) or non-parallel (not shown) with each other. When the two axes are non-parallel, an off-center design is created. When the first mounting body 300 (shown in FIG. 1) is attached to the second mounting body 200, an off-center design may offer additional degrees of freedom in a user's positioning of the device. FIG. 2D shows a front view of the second mounting body 200 as shown in FIG. 2A. It is appreciated that the relative position of the first portion 202, the second portion 204, the magnetic securing device 206, and the optional attachment portion 208 can be arranged in any desired manner and not be limited to the arrangement shown in FIG. 2A-FIG. 2D.

FIG. 3 illustrates a perspective view of a first mounting body 300 of the detachable mounting system 100 as illustrated in FIG. 1. As shown in FIG. 3, the first mounting body 300 includes a mounting end 302 and a magnetic mounting piece 306. The magnetic mounting piece 306 may also comprise a screw thread 304. In some exemplary embodiments, the first mounting body 300 is attached to or embedded within a back cover or a protective case of the electronic device 120, such as various generations of iPad®.

Referring to FIG. 3, the magnetic mounting piece 306 comprises at least one of a permanent magnet and a ferromagnetic material. In some exemplary embodiments, the magnetic mounting piece 306 comprises a neodymium (NdFeB, NIB, or Neo) magnet. The magnetic mounting piece 306 enables the magnetic securing of the first mounting body 300. For example, the magnetic mounting piece 306 can prevent the detaching of the first mounting body 300 from the second mounting body 200 caused by gravity, vibration, force of a user operation, or a combination thereof. As an example illustrated in FIG. 3, the magnetic mounting piece 306 can be a circular shape or a concentric shape. It is appreciated that any other desired shape may be implemented or used for obtaining a desired level of magnetic coupling. In some exemplary embodiments, the magnetic mounting piece 306 corresponds to the magnetic securing device 206 as shown in FIG. 2A, for creating a magnetic coupling. In some exemplary embodiments, only one of the magnetic securing device 206 and the magnetic mounting piece 306 may be required for creating a magnetic coupling.

Referring still to FIG. 3, the magnetic mounting piece 306 includes a screw thread 304 that is compatible with the securing and releasing latch 210 (shown in FIG. 2A) and a standard camera tripod using 1/4-20 UNC threads (not shown). Thus, the screw thread 304 enables the coupling of the securing and releasing latch 210, such as a screw, and coupling of a camera tripod, to the second mounting body 200. It is appreciated that the screw thread 304 can be any size or any shape that is compatible with the desired securing and releasing latch 210.

FIG. 4 illustrates a perspective view of an exemplary embodiment 500 of the first mounting body 300 being attached to the second mounting body 200 of the detachable mounting system 100 as illustrated in FIG. 1. As discussed above, in some exemplary embodiments, at least one of the magnetic mounting piece 306 (shown in FIG. 3) and the magnetic securing device 206 (shown in FIG. 2A) comprises one or both of a permanent magnet and a ferromagnetic material. As a result, the magnetic securing device 206, with or without the magnetic mounting piece 306, can magnetically secure the first mounting body 300 to the second mounting body 200 through magnetic force, which exists between the magnetic mounting piece 306 and the magnetic securing device 206. FIG. 4 illustrates that the first mounting body 300 is being coupled to the second mounting body 200 through magnetic force.

As a result of the magnetic force, the first mounting body 300 and the second mounting body 200 can be coupled and/or aligned easily or effortlessly while offering certain level of security against gravity, vibration, force of a user operation, or a combination thereof. The easy alignment created by the magnetic securing device 206 and/or the magnetic mounting piece 306 may also enable the securing and releasing latch 210, such as a screw, to be easily aligned and attached. As an example, the magnetic coupling may allow a user to tighten a screw with one hand, without the need to use the other hand to hold the device in position.

A typical electronic device, such as the electronic device 120, may require charging and/or signal communication. Thus, the detachable mounting system 100 can further include conductive contacts (not shown). The conductive contacts may be coupled with at least the first mounting body 300, for the purpose of charging and/or communicating with the electronic device 120. In some exemplary embodiments, the first mounting body 300 and the second mounting body 200 may each or both include conductive contacts for enabling the charging and/or signal communication of the electronic device 120. In addition, when the electronic device 120 is charging or communicating with an external power source or an external device, the electronic device 120 may still need to be rotated or manipulated. For example, a user may want to rotate the electronic device 120 horizontally for making a presentation or slideshow. Thus, to allow the electronic device 120 to rotate without affecting the conductive coupling or signal communication, one or both of the first mounting body 300 and the second mounting body 200 may include co-centric, partially co-centric, or other conductive traces for the conductive couplings.

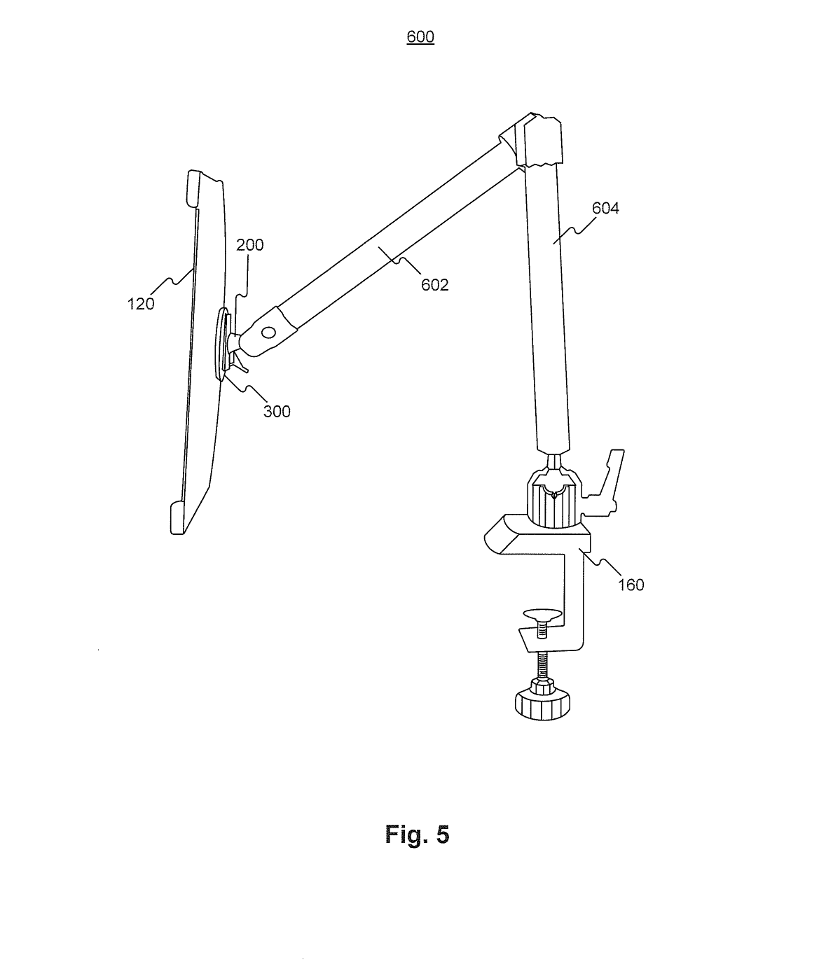

FIG. 5 illustrates a view of an exemplary embodiment 600 of the detachable mounting system 100 as shown in FIG. 1. The exemplary embodiment 600 includes the electronic device 120; the first mounting body 300; and the second mounting body 200, which may include one or more of a first arm 602 and a second arm 604. The exemplary embodiment 600 also includes the supporting base or surface 160. The electronic device 120, the first mounting body 300 and the second mounting body 200 (not including the arms 602 and 604) are similar or substantially similar to those described above and thus are not repeatedly described here.

FIG. 5 shows, as an example, that the supporting base or surface 160 is a clamp. The supporting base or surface 160 may also have various configurations, such as a metal or otherwise heavy, stabilized, or mounted base; a ceiling or top mount for attaching to a wall or surface; a base for screw- or adhesive-mounted configuration; a dashboard, seatback, headrest, vent, window, sunroof, or center console mount for vehicles; or some combination thereof. It is appreciated that these are merely exemplary variations, and the design and configuration may vary to provide the stability and/or needed for various applications of users. The supporting base or surface 160 can enable the securing of the detachable mounting system 100 to a wall, desk, ceiling, shelf, cabinet, vehicle dashboard, vehicle seatback, vehicle headrest, vehicle vent, vehicle window, vehicle roof or sunroof, and vehicle center console, etc.

In some exemplary embodiments, as illustrated in FIG. 5, at least one movable arm (602 or 604) is coupled with the magnetic securing device 206 (an example is shown in FIG. 2A) of the second mounting body 200 and the supporting base or surface 160. In addition, the two arms 602 and 604, as shown in FIG. 5, can be coupled with a joint between them, for providing at least one degree of freedom between the two arms. Furthermore, at least one of the two arms (602 or 604) is coupled to the supporting base or surface 160 through a clamp, a screw mount, a wall/desk/ceiling mounting piece, a joint, and a dashboard, seatback, headrest, vent, window, sunroof, or center console mount for vehicles. The moveable arms can enable at least one of relative horizontal, vertical, pivoting, swiveling, and rotating movements of the electronic device 120 relative to supporting base or surface 160.

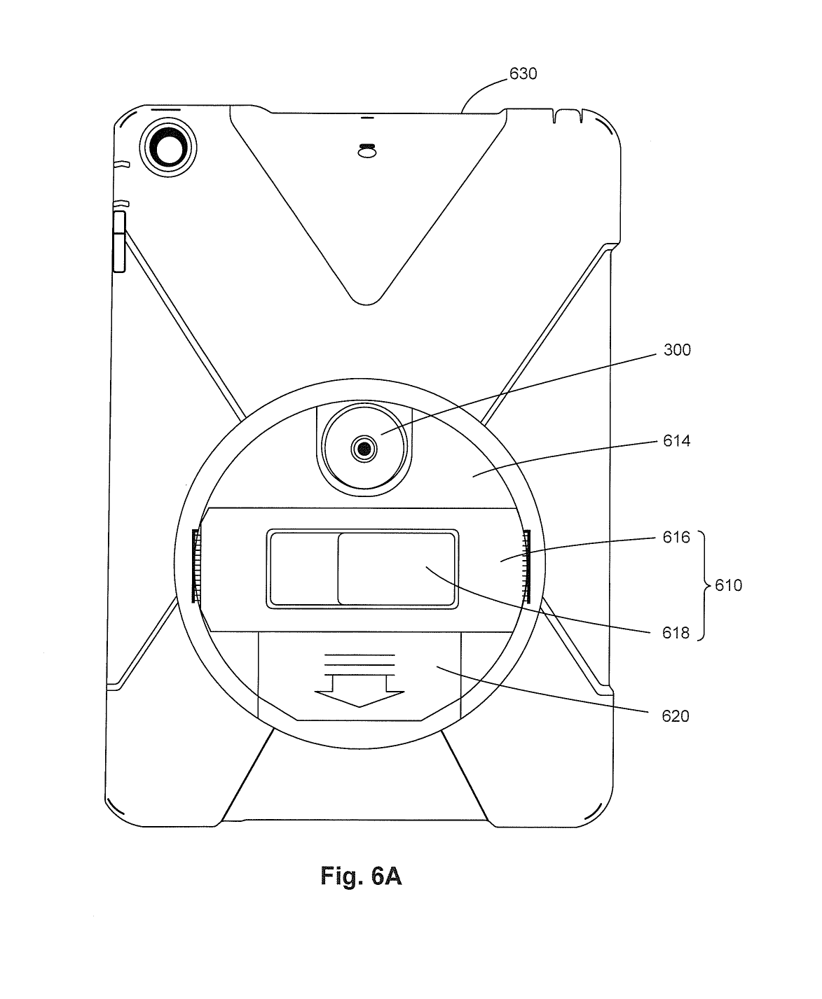

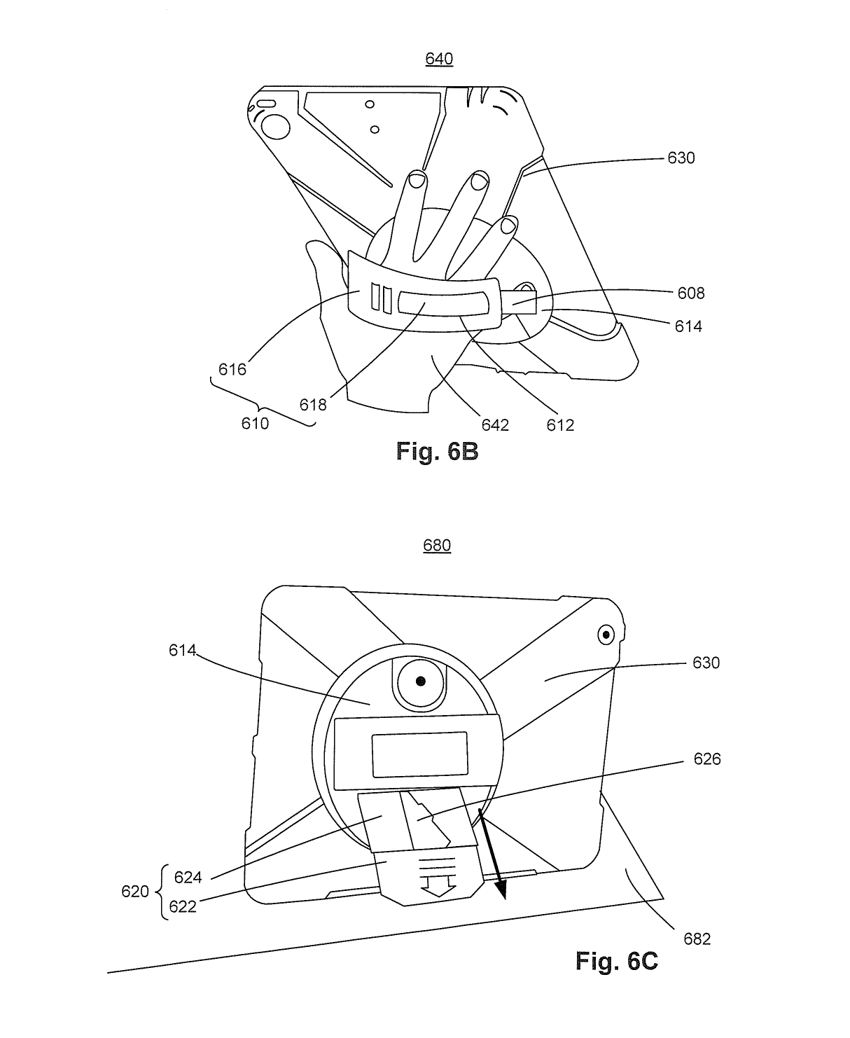

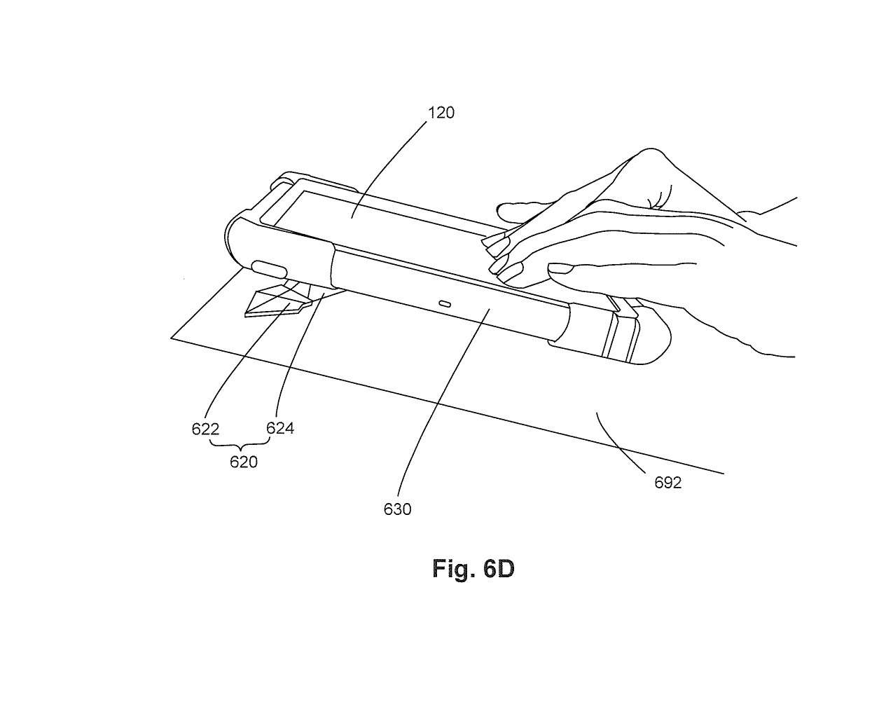

FIG. 6A illustrates an exemplary embodiment of a protective housing 630 that includes a rotatable platform 614. The protective housing 630 may include a protective case that is capable to be mounted with the electronic device 120. The first mounting body 300 may include, for example, the mounting end 302, the screw thread 304, and the magnetic mounting piece 306 (shown in FIG. 3). The first mounting body 300 is described above and therefore not described again here. As shown in FIG. 6A, in some embodiments, the shape of the first mounting body 300 may correspond to the shape of a recess of the rotatable platform 614. For example, the rotatable platform 614 may include a substantially disk shaped recess or a half-round shaped recess to allow access to the first mounting body 300.

Referring to FIG. 6A, the rotatable platform 614 can be rotatably mounted to or integrated with the protective housing 630. For example, the rotatable platform 614 can be rotatably mounted to the protective housing 630 using a screw, a hinge, an axle, etc. The rotatable platform 614 can also be integrated with the protective housing 630 as one integral piece. In some embodiments, the rotatable platform 614 may rotate any degree with respect to the protective housing 630. For example, the rotatable platform 614 can rotate 90 degrees or 180 degrees with respect to the protective housing 630, and therefore allow the electronic device mounted in the protective housing 630 to be viewed at a portrait or landscape orientation. It is appreciated that the rotatable platform 614 can also rotate any other number of degrees with respect to the protective housing 630.

Referring still to FIG. 6A, in some embodiments, the rotatable platform 614 may include a hand-strap 610 and a pullout stand 620. The hand-strap 610 is described in greater detail below with respect to FIG. 6B.

FIG. 6B illustrates a perspective view of an exemplary embodiment 640 of the protective housing 630 that includes the rotatable platform 614. The rotatable platform 614 includes the hand-strap 610. In some embodiments, the hand-strap 610 may be flexible or extendable to allow a user to slide a hand 642 under the hand-strap 610 to carry the protective housing 630 and the attached electronic device 120. In some embodiments, the hand-strap 610 may include a flexible handle 616 and a strap 618.

The flexible handle 616 can be, for example, a rectangular parallelepiped with an opening 612. The flexible handle 616 may have an inner surface facing towards the rotatable platform 614 and an outer surface facing away from the rotatable platform 614. The inner surface may be in contact with the user's hand 642 and therefore may be smooth to enhance the user's experience. The outer surface may be rugged, patterned, ribbed, or foamed to improve the resistance to wear, tear, and impact. In some embodiments, the flexible handle 616 may include a gap (not shown) between its inner surface and its outer surface. The gap can be used to accommodate the strap 618. For example, the strap 618 can be inserted through the gap such that a portion of the strap 618 is positioned between the inner surface and outer surface of the flexible handle 616. The flexible handle 616 may be made of, for example, elastic materials, plastics, soft rubber, hard rubber, or any combination thereof that are suitable.

In some embodiments, the flexible handle 616 also includes an opening 612. The opening 612 may be, for example, a rectangular shaped opening. The strap 618 may be accessible through the opening 612. In some embodiments, the strap 618 includes adjustment mechanisms such as a hook and loop fasteners to enable the adjustment of the length of the strap 618. The opening 612 allows the access to the strap 618 for adjustment of the strap 618.

Referring still to FIG. 6B, the strap 618 can be attached to the rotatable platform 614 at two ends 608. In some embodiments, the rotatable platform 614 may include one or more slots for receiving the ends 608 of the strap 618. For example, two slots may be included in the two opposing edges of the circumference of the rotatable platform 614. The strap 618 can be attached to the rotatable platform 614 using the two slots. As a result of the attachment, the rotatable platform 614 can be rotated using the strap 618. For example, a twisting or rotational motion imparted by the user's hand 642 can cause the rotatable platform 614 to rotate with respect to the protective housing 630. The strap 618 may be made of nylon, fabric, rubber, plastic, a combination thereof, or any other stretchable materials. While FIG. 6B illustrates the hand-strap 610 as having the flexible handle 616 and the strap 618, it is appreciated that the hand-strap 610 can also be one integral piece made of stretchable or flexible materials.

Referring back to FIG. 6A, the rotatable platform 614 can also include a pullout stand 620. FIG. 6A illustrates one exemplary embodiment of the pullout stand 620 in a non-extended position. When the pullout stand 620 is in a non-extended position, the lower outer edge of the pullout stand 620 is located substantially within a portion of the circumference of the rotatable platform 614. As a result, the pullout stand 620 can rotate together with the rotatable platform 614. The pullout stand 620 is described in greater detail with respect to FIG. 6C.

FIG. 6C illustrates another perspective view of an exemplary embodiment of the protective housing 630 that includes the rotatable platform 614 having the pullout stand 620. As shown in FIG. 6C, the pullout stand 620 can be extended or slid out from the rotatable platform 614 to support the protective housing 630 (and the electronic device attached to the protective housing 630) on a surface 682. In some embodiments, the pullout stand 620 includes a first portion 622 and a second portion 624. The lower, outer edge of the first portion 622 can provide support to the protective housing 630 on the surface 682. While FIG. 6C illustrates that the pullout stand 620 supports the protective housing 630 in a landscape position, the pullout stand 620 can also rotate with the rotatable platform 614 such that it supports the protective housing 630 in a portrait position.

Referring to FIG. 6C, the second portion 624 of the pullout stand 620 connects the first portion 622 to the rotatable platform 614. In some embodiments, the second portion 624 is an integral piece formed with the first portion 622. In some embodiments, the second portion 624 may hingedly, rotatably, movably, permanently, detachably, or latchably attach to the first portion 622. When the pullout stand 620 is not extended or retracted from its extended position, the second portion 624 can be slidably inserted to a gap or a space (not shown) between the rotatable platform 614 and the protective housing 630.

As shown in FIG. 6C, in some embodiments, the second portion 624 of the pullout stand 620 includes a supporting piece 626. The supporting piece 626 may be located in a cut-out region of the second portion 624 and attached to the second portion 624 along, for example, a left edge of the supporting piece 626. The supporting piece 626 is detached from the second portion 624 along its other edges. For example, FIG. 6C illustrates that the second portion 624 has a cut-out region in a middle area. The supporting piece 626 is located in the cut-out region and has substantially the same shape as the cut-out region. The supporting piece 626 may be flexibly or hingedly attached to the second portion 624 at the left edge of the supporting piece 626 and may rotate around the left edge of the supporting piece 626. The supporting piece 626 is detached from the second portion 624 at its other edges. The supporting piece 626 may thus rotate any number of degrees (e.g., 90 degrees) around its left edge. In some embodiments, the supporting piece 626 rotates to a position such that at least a portion of a second edge (e.g., the right edge) of the supporting piece 626 can be movably attached to (e.g., inserted to) the rotatable platform 614. For example, as shown in FIG. 6C, the right edge of the supporting piece 626 includes a projecting portion, which may be inserted or snapped into a corresponding slot or space (not shown) of the rotatable platform 614. As a result of such attachment, the supporting piece 626 may hold the pullout stand 620 in one or more preconfigured angles (e.g., a 65° angle, a 75° angle, etc.) with respect to the protective housing 630.

FIG. 6D illustrates another perspective view of an exemplary embodiment of the protective housing 630 that includes the rotatable platform 614 having the pullout stand 620. As shown in FIG. 6D, in some embodiments, the second portion 624 of the pullout stand 620 may be flexible such that it can bend or rotate any number of degrees with respect to an edge (e.g., the upper edge) that attaches the pullout stand 620 to the rotatable platform 614 (shown in FIG. 6C). For example, the second portion 624 can bend or rotate more than 90 degrees (e.g., 130 degrees or 150 degrees) to support the protective housing 630 at an angle such that a user can comfortably operate (e.g., type) the electronic device 120 attached to the protective housing 630. While FIG. 6D illustrates that the pullout stand 620 supports the protective housing 630 in a portrait position, the pullout stand 620 can also rotate with the rotatable platform 614 such that it supports the protective housing 630 in a landscape position.

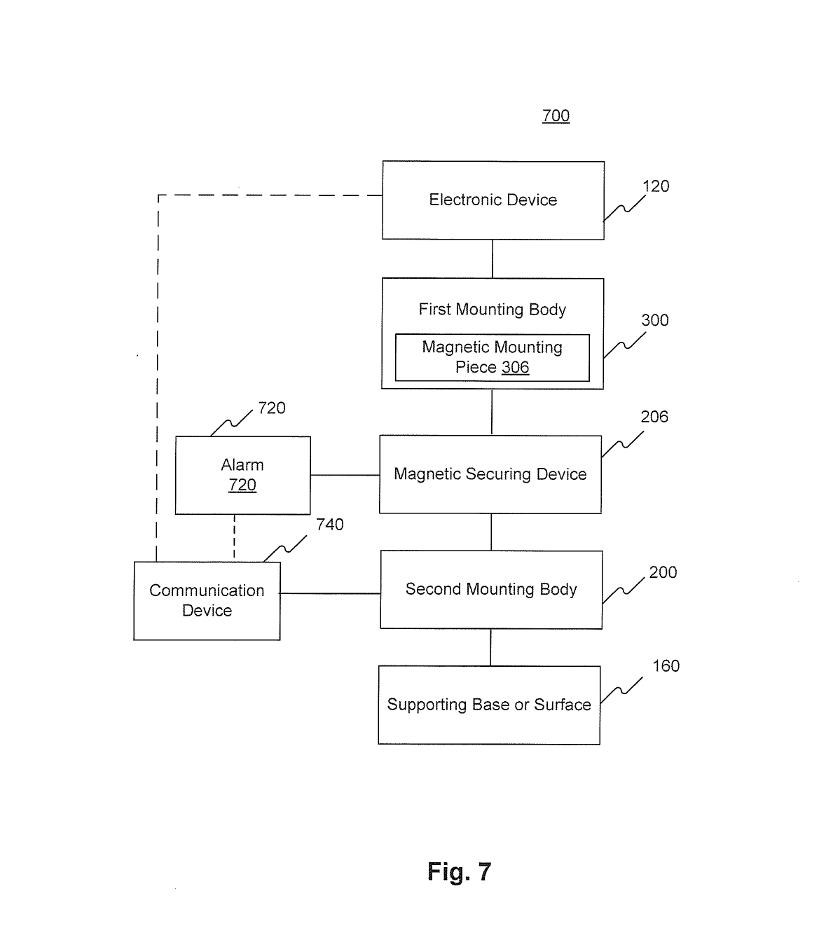

FIG. 7 illustrates a block diagram of an exemplary embodiment of a detachable mounting system 700. Detachable mounting system 700 can be used for securing an electronic device 120. Similar to those described above with respect to detachable mounting system 100, detachable mounting system 700 may include the first mounting body 300 that is coupled with the electronic device 120. The first mounting body 300 may include the magnetic mounting piece 306 (shown in FIG. 3). The detachable mounting system 700 also includes the second mounting body 200 that is capable of being coupled with the supporting base or surface 160. The second mounting body 200 may include a first end for being coupled to the first mounting body 300, and a second end for being coupled with the supporting base or surface 160. The detachable mounting system 700 also includes the magnetic securing device 206. The electronic device 120, the first mounting body 300, the second mounting body 200, the magnetic securing device 206, and the supporting base or surface 160 are described above and thus are not further described here.

Referring to FIG. 7, in some embodiments, the magnetic securing device 206 may be electrically coupled to an alarm 720, such as a security alarm. The alarm 720 may provide an audio alarm, a visual alarm, an audio-visual combined alarm, an electronic alerting system that is capable of being controlled by a user input, or any other alarm system. The alarm 720 can be triggered if one or more conditions are satisfied. For example, the alarm 720 can include a siren that generates a loud noise. The one or more conditions that trigger the alarm 720 may be, for example, a detachment of the magnetic securing device 206 from the magnetic mounting piece 306 of the first mounting body 300. As an example, the alarm 720 may be electrically coupled to the magnetic securing device 206 and/or the magnetic mounting piece 306 using a piece of conductor (e.g., an electrical wire). If the magnetic securing device 206 is physically disconnected or detached from the magnetic mounting piece 306, the alarm 720 may be triggered due to, for example, a break of the electrical conductivity associated with the conductor.

As another example, the alarm 720 may be coupled to the magnetic securing device 206 and/or the magnetic mounting piece 306 using a sensor, such as a magnetic field sensor (not shown). The magnetic field sensor can detect changes and disturbances in a magnetic field such as flux, strength, coupling, decoupling, and direction. The change of a magnetic field is detectable by the change of the force or interaction of the magnetic field with the sensor. For example, a magnetic field sensor can interact with a magnetic field such that a change of the magnetic field causes change in a voltage signal or current signal that the magnetic field sensor generates. Accordingly, the magnetic field sensor may detect the coupling or decoupling between the magnetic securing device 206 and the magnetic mounting piece 306 based on the change of magnetic field. After the magnetic field sensor detects such coupling or decoupling, it may trigger the alarm 720. For example, if the magnetic field sensor detects that the magnetic securing device 206 is decoupled from the magnetic mounting piece 306, it may send an electrical signal to the alarm 720 to trigger the siren.

While FIG. 7 illustrates that the alarm 720 is coupled to the magnetic securing device 206, the alarm 720 may be coupled to (e.g., integrated with) one or more of the magnetic securing device 206, the first mounting body 300, or the second mounting body 200. For example, the siren of the alarm 720 may be integrated as part of the second mounting body 200, while the sensor or conductor of the alarm 720 may be integrated with the magnetic securing device 206. The alarm 720 may also be a standalone device that is electrically coupled to magnetic securing device 206, the first mounting body 300, or the second mounting body 200. The interaction of the alarm 720 and the communication device 740 is described in more detail below.

As shown in FIG. 7, in some embodiments, a communication device 740 may be coupled to the second mounting body 200. The communication device 740 may include hardware (e.g., CPUs or processors, memories, communication interfaces, I/O subsystems, sensors, etc.) and/or software, for enabling wired and/or wireless communications. The processors or CPUs of the communication device 740 can be a single or multiple microprocessors, field-programmable gate arrays (FPGAs), or digital signal processors (DSPs) capable of executing particular sets of instructions stored in a memory or a cache. The memory can include a tangible and/or non-transitory computer-readable medium, such as a flexible disk, a hard disk, a CD-ROM (compact disk read-only memory), a flash drive, an MO (magneto-optical) drive, a DVD-ROM (digital versatile disk read-only memory), a DVD-RAM (digital versatile disk random-access memory), flash memory, a cache, a register, or a semiconductor memory.

The communication device 740 facilitates short range as well as long range wireless or wired communication using, for example, near field communication (NFC) protocols, Wi-Fi communication protocols, and/or cellular communication protocols. Near field communication may enable the communication device 740 to establish a short range wireless communication with other devices in its vicinity, such as the electronic device 120 and the alarm 720. For example, the communication device 740 can communicate, based on Bluetooth protocols, with the electronic device 120 and the alarm 720. In some embodiments, the communication device 740 may include a Bluetooth module, such as INNOVATI's general purpose Bluetooth module.

Referring to FIG. 7, in some embodiments, the communication device 740 communicates with the electronic device 120 to receive and transmit signals. For example, the communication device 740 can activate or deactivate the alarm 720 based on user inputs received at the electronic device 120. The electronic device 120 may receive a user input (e.g., a touch-screen gesture) indicating that the user desires to activate or deactivate the alarm 720. Based on the user input, the electronic device 120 sends a wireless or wired signal to the communication device 740 to request activating or deactivating the alarm 720. If the alarm 720 is activated, it may be triggered based on certain conditions (e.g., detachment of the magnetic securing device 206 from the magnetic mounting piece 306) as described above. If the alarm 720 is deactivated, it may not be triggered even if certain conditions are satisfied for triggering the alarm 720 (e.g., the magnetic securing device 206 is detached from the magnetic mounting piece 306).

After receiving the wired or wireless signal from the electronic device 120, the communication device 740 may communicate to the alarm 720 a signal that reflects the request for activating or deactivating the alarm 720. As a result, the alarm 720 activates or deactivates based on the request signal. In some embodiments, the alarm 720 may communicate one or more status signals to the communication device 740. The one or more status signals indicate the status of the alarm 720 and/or the status of the attachment or detachment of the magnetic securing device 206 and magnetic mounting piece 306. As an example, the alarm 720 may send an alarm status signal to the communication device 740 indicating that it is activated or deactivated. The communication device 740 may thus transmit the alarm status signal to the electronic device 120, which can display the corresponding alarm status on the screen of the electronic device 120. As a result, the electronic device 120 can provide the alarm status of the alarm 720 to the user.

As another example, after the alarm 720 activates or deactivates based on the signal that reflects the request for activating or deactivating the alarm 720, the alarm 720 or the communication device 740 may monitor the status of the attachment or detachment of the magnetic securing device 206 and magnetic mounting piece 306. In some embodiments, the alarm 720 monitors the status and if the alarm 720 detects that the magnetic securing device 206 is detached from the magnetic mounting piece 306, it sends a status signal to the communication device 740. In some embodiments, the communication device 740 monitors the status and notifies the alarm 720 when the detachment occurs or when the attachment ceases to exist. Based on the attachment/detachment status signal, the communication device 740 may communicate to the electronic device 120 to provide the status of the detachment or attachment. The electronic device 120 is capable of displaying the corresponding attachment/detachment status on the screen of the electronic device 120. As a result, the electronic device 120 can also provide the attachment/detachment status to the user. The attachment/detachment status indicates whether the magnetic securing device 206 is attached or detached from the magnetic mounting piece 306. It is appreciated that the alarm 720 and/or the communication device 740 can also monitor and record any other information associated with the status of the alarm and the status of the attachment/detachment (e.g., the time and the location associated with the attachment/detachment), and provide such information to the electronic device 120.

While FIG. 7 illustrates that the communication device 740 is physically coupled to the second mounting body 200, the communication device 740 may be physically coupled to (e.g., integrated with) one or more of the first mounting body 300, the second mounting body 200, or the magnetic securing device 206. The communication device 740 may also be a standalone device that is electrically coupled to the magnetic securing device 206, the first mounting body 300, or the second mounting body 200. Further, the communication device 740 may also be integrated with the alarm 720.

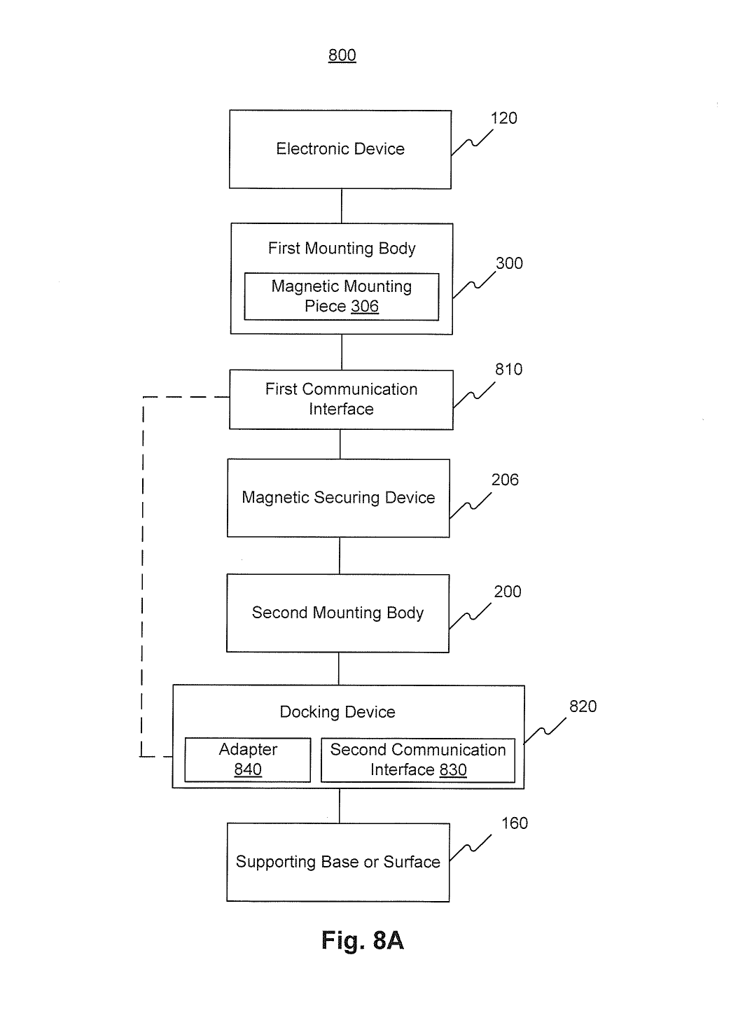

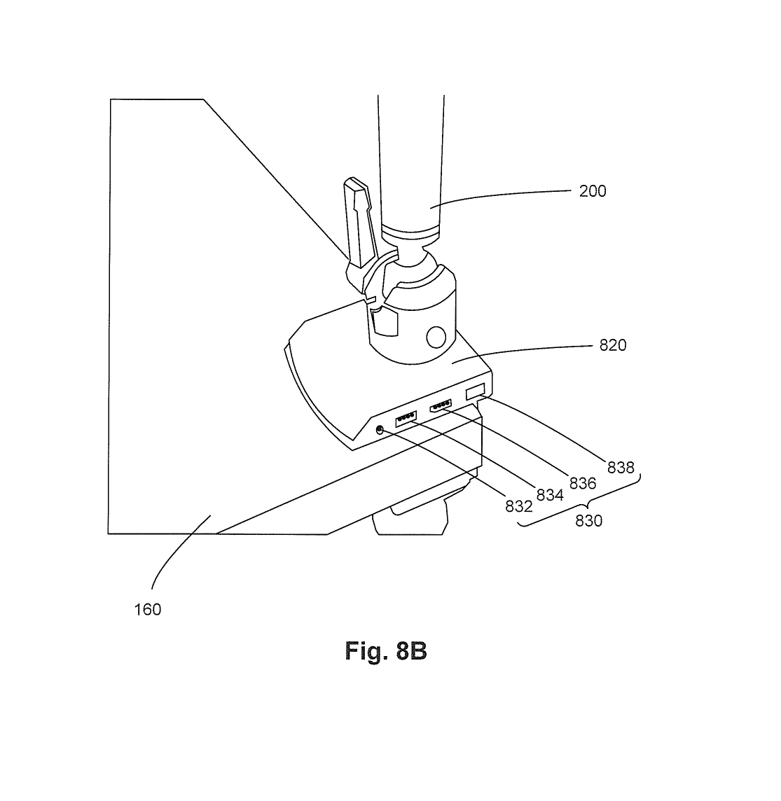

FIG. 8A illustrates a block diagram of an exemplary embodiment of a detachable mounting system 800. Detachable mounting system 800 can be used for securing the electronic device 120. Similar to those described above with respect to detachable mounting system 100, detachable mounting system 800 may include the first mounting body 300 that is coupled with the electronic device 120. The first mounting body 300 may include the magnetic mounting piece 306. The detachable mounting system 800 also includes the second mounting body 200 that is capable of being coupled with the supporting base or surface 160. The second mounting body 200 may include a first end for being coupled to the first mounting body 300, and a second end for being coupled with the supporting base or surface 160. The detachable mounting system 800 also includes the magnetic securing device 206. The electronic device 120, the first mounting body 300, the second mounting body 200, the magnetic securing device 206, and the supporting base or surface 160 are described above and thus are not further described here.

Referring to FIG. 8A, the detachable mounting system 800 may also include a first communication interface 810 and a docking device 820. The docking device 820 may include a second communication interface 830. The first communication interface 810, the docking device 820, and the second communication interface 830 can be used for providing signal communication and/or charging for the electronic device 120.

In some embodiments, the first communication interface 810 may include one or more connectors adapted to communicate with the electronic device 120. For example, the first communication interface may include one or more of an APPLE LIGHTENING connector, a 30-pin dock connector, a Universal Serial Bus (USB) connector, a micro-USB connector, a USB Type-C connector, and a High Definition Multimedia Interface (HDMI) connector. In some embodiments, the first communication interface 810 may be detachably coupled to or integrated with one or more of the first mounting body 300, the magnetic mounting piece 306, the magnetic securing device 206, and the second mounting body 200. As an example, the first communication interface 810 may be physically attached to or integrated with the first end of the second mounting body 200 to provide a communication interface to the electronic device 120.

Referring to FIG. 8A, the first communication interface 810 may facilitate wired or wireless communication with the docking device 820. As an example, the first communication interface 810 may be electrically coupled to a cable (not shown) for communicating to the docking device 820. As another example, the first communication interface 810 and/or the docking device 820 may include hardware (e.g., processors, memories, communication interfaces, I/O subsystems, sensors, etc.) and/or software, for enabling wired and/or wireless communications (e.g., near field communication) between them. For example, the docking device 820 can communicate, based on Bluetooth protocols, with the first communication interface 810. In some embodiments, the first communication interface 810 and/or the docking device 820 may each include a Bluetooth module, such as INNOVATI's general purpose Bluetooth module.

Referring to FIG. 8A, the docking device 820 can include the second communication interface 830 that provides one or more communication ports. For example, the second communication interface 830 may include at least one of a universal serial bus (USB) port, a hub, an Ethernet port, a display port, an APPLE LIGHTNING port, an HDMI port, an audio interface, a memory card interface, a PCI or PCI express interface, a network interface controller (NIC) port, a serial interface port, and a power connector. In some embodiments, the docking device 820 is a port replicator, which relays, duplicates, repeats, or magnifies the signals received from the one or more ports of the second communication interface 830 to the first communication interface 810. For example, the docking device 820 may repeats signals from a USB port of the second communication interface 830 and relays the signals to a USB connector of the first communication interface 810.

In some embodiments, the docking device 820 may include an adapter 840. The adapter 840 can convert signals received from the one or more ports (e.g., the Ethernet port, the HDMI port, the hub, or the audio interface) of the second communication interface 830 to the signals used in the first communication interface 810. For example, the adapter 840 may include circuits or systems that convert the signals received from one or more of the Ethernet port, the HDMI port, the hub, or the audio interface to signals that are compatible with a USB channel. The adapter 840 may therefore be a USB-based adapter. The adapter 840 may also be an APPLE THUNDERBOLT-based adapter, which may convert signals received from one or more of the Ethernet port, the HDMI port, the memory interface card, or the audio interface to signals that are compatible with a THUNDERBOLT channel. The converted signals may be communicated to the electronic device 120 using a USB connector or a THUNDERBOLT connector of the first communication interface 810.

Referring to FIG. 8A, the docking device 820 may be a standalone device or integrated with the second mounting body 200. As discussed above, the second mounting body 200 may be physically coupled to the support base or surface 160.

FIG. 8B illustrates a perspective view of an exemplary embodiment of the docking device 820 including the second communication interface 830. As shown in FIG. 8B, the docking device 820 may be integrated with the second end of the second mounting body 200. The docking device 820 may include, for example, a power connector 832, a USB port 834, an HDMI port 836, and an Ethernet port 838. It is appreciated that any other communication port or connectors may be included in the second communication interface 830.

Some of the methods disclosed herein may be implemented as a computer program product, i.e., a computer program tangibly embodied in an information carrier, e.g., in a machine readable storage device, for execution by, or to control the operation of, data processing apparatus, e.g., a programmable processor, a computer, or multiple computers. A computer program can be written in any form of programming language, including compiled or interpreted languages, and it can be deployed in any form, including as a standalone program or as a module, component, subroutine, or other unit suitable for use in a computing environment. A computer program can be deployed to be executed on one computer or on multiple computers at one site or distributed across multiple sites and interconnected by a communication network.

The accompanying drawings and pictures are solely for illustrating certain embodiments, exemplary aspects, and optional designs of the disclosed embodiments. Therefore, the specific designs, dimensions, shapes, and configurations illustrated here and described above are not intended to and do not limit the scope of the disclosed embodiments. Moreover, it will be apparent to those skilled in the art from consideration of the specification and practice of the present disclosure that various modifications and variations can be made to the disclosed systems without departing from the scope of the disclosure. Therefore, the specification and examples are exemplary only, with the intended scope described in the claims.

What is claimed is:

1. A detachable mounting system for securing an electronic device, comprising:
a protective housing for mounting to the electronic device, the protective housing including a mounting piece;
a base capable of being coupled with a supporting surface, the base comprising:
a first end coupled to the protective housing,
a second end capable of being coupled with the supporting surface, wherein at least one of couplings with the first and second ends enables at least one of relative horizontal, vertical, pivoting, swiveling, and rotating movements of the electronic device relative to the supporting surface;
a securing device detachably coupled between the protective housing and the first end of the base for securing the protective housing to the first end of the base through at least magnetic force between the mounting piece and the securing device;
a security alarm coupled to the security device, the security alarm being capable of detecting at least one of an attachment or detachment of the mounting piece to or from the securing device; and
a communication device electrically coupled to the security alarm, the communication device being configured to communicate to the security alarm a signal representing at least one of the attachment and the detachment.

2. The detachable mounting system of claim 1, wherein the securing device comprises a securing and releasing latch that includes at least one of an electrically-controlled lock or magnet, a screw, a clamp, and a quick-release latch coupled with the magnetic mounting piece.

3. The detachable mounting system of claim 1, wherein the mounting piece has a screw thread compatible with a standard camera tripod using 1/4-20 UNC threads.

4. The detachable mounting system of claim 1, wherein at least one of the mounting piece and the securing device comprises at least one of a permanent magnet and a ferromagnetic material.

5. The detachable mounting system of claim 1, wherein at least one of the mounting piece and the securing device comprises a neodymium (NdFeB, NIB, or Neo) magnet.

6. The detachable mounting system of claim 1, wherein the first end of the base comprises a ball, a T-ball, or a substantially spherical joint.

7. The detachable mounting system of claim 1, wherein the base comprises at least one movable or extendable arm for providing maneuverability and freedom of movement of the electronic device.

8. The detachable mounting system of claim 1, wherein the second end of the base comprises at least one of a clamp, a screw mount, a wall/desk/ceiling mounting piece, and a dashboard, seatback, headrest, vent, window, sunroof, or center console mount for vehicles.

9. The detachable mounting system of claim 1, further comprising conductive contacts coupled with at least the protective housing for providing a charging function to or a signal communication function with the electronic device.

10. The detachable mounting system of claim 1, wherein the electronic device comprises one of a tablet PC, a tablet, and a smartphone.

11. The detachable mounting system of claim 1, wherein the communication device is further configured to communicate wirelessly with the electronic device to receive a user input for activating or deactivating the security alarm.

12. The detachable mounting system of claim 11, wherein the communication device is configured to notify the security alarm when the detachment occurs or when the attachment ceases to exist.

13. The detachable mounting system of claim 1, wherein the communication device facilitates communication using at least one of a near-field communication protocol, a Wi-Fi communication protocol, and a cellular communication protocol.

14. The detachable mounting system of claim 1, wherein the security alarm comprises at least one of an audio alarm, a visual alarm, an audio-visual combined alarm, or an electronic alerting system that is controlled by a user input.

15. The detachable mounting system of claim 1, wherein the protective housing comprises a rotatable platform that is rotatable with respect to a surface of the protective housing, the rotatable platform including at least one of a hand-strap and a pullout stand.

16. The detachable mounting system of claim 15, wherein the hand-strap comprises a flexible strap having an adjustable length.

17. The detachable mounting system of claim 15, wherein the pullout stand is slidably or insertably coupled to the rotatable platform and is configured to at least partially extend in a direction that is substantially co-planar to a face of the rotatable platform.

18. The detachable mounting system of claim 15, wherein the pullout stand comprises a first portion and a second portion, the first portion being integrally or hingedly coupled to the second portion, wherein the first portion is configured to extend at least partially outside of the circumferences of the rotatable platform.

19. The detachable mounting system of claim 1, further comprising:
a first communication interface electrically coupled to the electronic device, the first communication interface including one or more connectors adapted to communicate with the electronic device; and
a docking device coupled to the base, the docking device including a second communication interface and one or more adapters configured to facilitate communication or convert signals between the first communication interface and the second communication interface, wherein the second communication interface includes one or more communication ports configured to communicate with one or more external devices.

20. The detachable mounting system of claim 19,
wherein the one or more connectors of the first communication interface comprises at least one of: a LIGHTENING connector, a 30-pin dock connector, a USB connector, a micro-USB connector, a USB Type-C connector, and an HDMI connector; and
wherein the one or more communication ports of the second communication device includes at least one of a universal serial bus (USB) port, a hub, an Ethernet port, a display port, an LIGHTENING port, a THUNDERBOLT port, an HDMI port, an audio interface, and a power connector.

21. A detachable mounting system for securing an electronic device, comprising:
a protective housing for mounting to the electronic device, the protective housing comprising a mounting piece;
a base capable of being coupled with a supporting surface, the base comprising:
a first end coupled to the protective housing,
a second end capable of being coupled with the supporting surface, wherein at least one of couplings with the first and second end enables at least one of relative horizontal, vertical, pivoting, swiveling, and rotating movements of the electronic device relative to the supporting surface;
a securing device detachably coupled between the protective housing and the first end of the base for securing the protective housing to the first end of the base through at least magnetic force between the mounting piece and the securing device; and
a docking device integrated with the base, wherein the docking device is configured to facilitate communication or convert signals between the electronic device and one or more external devices.

22. A detachable mounting system for securing an electronic tablet, comprising:
a protective housing for mounting to the electronic tablet, the protective housing comprising a mounting piece and a rotatable platform that is rotatable with respect to a surface of the protective housing, the rotatable platform including a hand-strap and a pullout stand;
a base capable of being coupled with a supporting surface, the base comprising:
a first end coupled to the protective housing,
a second end capable of being coupled with the supporting surface, wherein at least one of couplings with the first and second end enables at least one of relative horizontal, vertical, pivoting, swiveling, and rotating movements of the electronic tablet relative to the supporting surface; and
a securing device detachably coupled between the protective housing and the first end of the base for securing the protective housing to the first end of the second mounting body through at least magnetic force between the mounting piece and the securing device.
